(19) United States
(12) Patent Application Publication
(10) Pub. No.: US 2024/0038888 A1
(43) Pub. Date: Feb. 1, 2024

(54) SEMICONDUCTOR DEVICE

(71) Applicant: RENESAS ELECTRONICS CORPORATION, Tokyo (JP)

(72) Inventors: Makoto KOSHIMIZU, Tokyo (JP); Yasutaka NAKASHIBA, Tokyo (JP); Tohru KAWAI, Tokyo (JP)

(21) Appl. No.: 18/334,763

(22) Filed: Jun. 14, 2023

(30) Foreign Application Priority Data
Jul. 28, 2022 (JP) 2022-120665

(51) Int. Cl. H01L 29/78; H01L 27/088; H01L 29/06

(52) U.S. Cl. CPC H01L 29/7817; H01L 27/088; H01L 29/0615

(57) ABSTRACT

A semiconductor substrate includes an n-type substrate region, an n-type first semiconductor region and a second semiconductor region disposed at different positions on the n-type substrate region, an n-type buried layer formed on the n-type first semiconductor region and on the second semiconductor region, a p-type third semiconductor region and a p-type fourth semiconductor region formed on the n-type buried layer and spaced apart from each other, and an n-type fifth semiconductor region that reaches an upper surface of the semiconductor substrate from the n-type buried layer. The n-type buried layer, the n-type first semiconductor region, and the n-type substrate region are present under the p-type third semiconductor region and the n-type fifth semiconductor region. A first transistor is formed in an upper portion of the p-type third semiconductor region, and a second transistor is formed in an upper portion of the p-type fourth semiconductor region.

### CROSS-REFERENCE TO RELATED APPLICATIONS

The disclosure of Japanese Patent Application No. 2022-120665 filed on Jul. 28, 2022, including the specification, drawings and abstract is incorporated herein by reference in its entirety.

### BACKGROUND

The present disclosure relates to a semiconductor device, and can be suitably used, for example, for a semiconductor device including a transistor as a power switching element.

For example, a power switching element such as an LDMOSFET (Laterally Diffused Metal-Oxide-Semiconductor Field Effect Transistor) is used in a power conversion circuit such as an inverter circuit. Although the power switching element is formed in a semiconductor substrate, transistors constituting other circuits may be formed together in the semiconductor substrate in which the power switching element is formed.

There are disclosed techniques listed below.
[Patent Document 1] Japanese Unexamined Patent Application Publication No. 2013-247120
[Non-Patent Document 1] T. Nitta, Y. Yoshihisa, T. Kuroi, K. Hatasako, S. Maegawa and K. Onishi, “Enhanced active protection technique for substrate minority carrier injection in Smart Power IC,” 2012 24th International Symposium on Power Semiconductor Devices and ICs, Bruges, Belgium, 2012, pp. 205-208

Patent Document 1 and Non-Patent Document 1 describe techniques for semiconductor device having an active barrier structure.

### SUMMARY

In a semiconductor device having a power switching element, it is desired to improve performance as much as possible.

Other objects and novel features will become apparent from the description of this specification and the accompanying drawings.

According to one embodiment, a semiconductor device includes a semiconductor substrate, a first transistor of a first conductivity type formed in a first element region on an upper surface of the semiconductor substrate, and a second transistor formed in a second element region on the upper surface of the semiconductor substrate. The semiconductor substrate configuring the semiconductor device includes a substrate region of the first conductivity type reaching a back surface of the semiconductor substrate, and a first semiconductor region and a second semiconductor region disposed at different positions on the substrate region. The first semiconductor region is of the first conductivity type, and the second semiconductor region is of the first conductivity type or a second conductivity type opposite to the first conductivity type. The semiconductor substrate further includes: a buried layer of the first conductivity type formed on the first semiconductor region and the second semiconductor region; a third semiconductor region of the second conductivity type and a fourth semiconductor region of the second conductivity type that are formed on the buried layer and spaced apart from each other; and a fifth semiconductor region of the first conductivity type that reaches the upper surface from the buried layer. A first contact plug is disposed on the fifth semiconductor region and is electrically connected to the fifth semiconductor region. The buried layer, the first semiconductor region and the substrate region are present under the third semiconductor region and the fifth semiconductor region, and the buried layer, the second semiconductor region and the substrate region are present under the fourth semiconductor region. In plan view, the first element region is included in the third semiconductor region, and in plan view, the second element region is included in the fourth semiconductor region, and in plan view, the fifth semiconductor region is interposed between the third semiconductor region and the fourth semiconductor region.

According to one embodiment, the performance of the semiconductor device can be improved.

### BRIEF DESCRIPTION OF THE DRAWINGS

FIG. 1 is a cross-sectional view of a main portion of a semiconductor device according to one embodiment.

FIG. 2 is a plan view of the main portion of the semiconductor device according to one embodiment.

FIG. 3 is a circuit diagram showing an inverter circuit.

FIG. 4 is a circuit diagram showing the inverter circuit.

FIG. 5 is a circuit diagram showing the inverter circuit.

FIG. 6 is a cross-sectional view of a main portion of a semiconductor device according to one embodiment.

FIG. 7 is an explanatory diagram of the semiconductor device according to one embodiment.

FIG. 8 is a cross-sectional view of a main portion of a semiconductor device according to another embodiment.

FIG. 9 is a cross-sectional view of the main portion of the semiconductor device according to another embodiment.

FIG. 10 is a cross-sectional view of the main portion of the semiconductor device according to another embodiment.

### DETAILED DESCRIPTION

In the following embodiments, when required for convenience, the description will be made by dividing into a plurality of sections or embodiments, but except when specifically stated, they are not independent of each other, and one is related to the modified example, detail, supplementary description, or the like of part or all of the other. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle. Furthermore, in the following embodiments, it is needless to say that the constituent elements (including element steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above numerical values and ranges.

Hereinafter, embodiments will be described in detail based on the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In the drawings used in the embodiments, hatching may be omitted even in the case of cross-sectional view in order to make the drawings easier to see. Also, even in the case of plan view, hatching may be used to make the drawing easier to see.

### First Embodiment

### Structure of Semiconductor Device

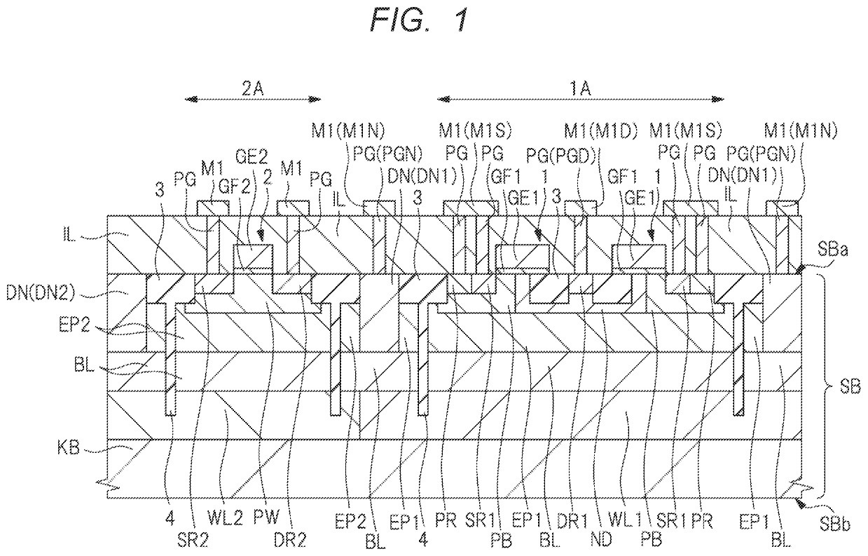

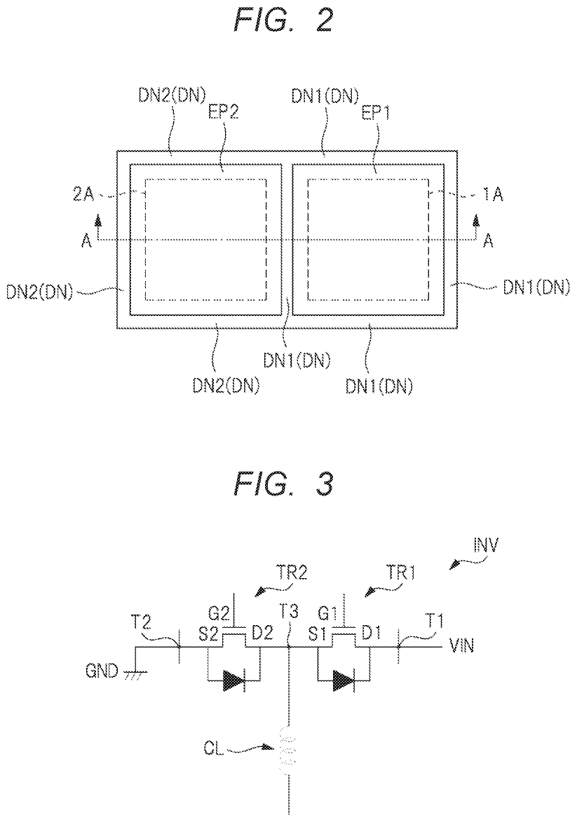

A semiconductor device according to the first embodiment of the present disclosure will be described referring to the drawings. FIG. 1 is a cross-sectional view of a main portion of a semiconductor device according to the present embodiment. FIG. 2 is a plan view of the main portion of the semiconductor device according to the present embodiment. The cross-sectional view along A-A line in FIG. 2 substantially corresponds to FIG. 1.

The semiconductor device of the present embodiment includes a power switching element used in a power conversion circuit such as an inverter circuit, and includes an LDMOSFET as a transistor constituting the power switching element.

In the present application, the MOSFET (Metal Oxide Semiconductor Field Effect Transistor) or the LDMOSFET are not only the MISFET using an oxide film (silicon oxide film) as a gate dielectric film but also the MISFET using a dielectric film other than the oxide film (silicon oxide film) as the gate dielectric film. Also, the LDMOSFET is a kind of MISFET (Metal Insulator Semiconductor Field Effect Transistor) element. The LDMOSFET may also be referred to as HV-MOSFET (High Voltage Metal Oxide Semiconductor Field Effect Transistor) or DEMOSFET (Drain Extended Metal Oxide Semiconductor Field Effect Transistor).

In addition, an n-channel MISFET (transistor) can be regarded as an n-type MISFET (transistor), and a p-channel MISFET (transistor) can be regarded as a p-type MISFET (transistor). In this case, the n-type means that the conductivity type of the channel at the time of turning on is the n-type, and the p-type means that the conductivity type of the channel at the time of turning on is the p-type. Hereinafter, a transistor formed in an element region 1A will be described as an n-type (n-channel) transistor.

Hereinafter, the structure of the semiconductor device of the present embodiment will be described in detail referring to FIG. 1.

A semiconductor substrate SB configuring the semiconductor device of the present embodiment is made of monocrystalline silicon and the like. The semiconductor substrate SB has an upper surface SBa and a back surface SBb opposite to the upper surface SBa. The upper surface SBa of the semiconductor substrate SB includes the element region 1A in which a transistor (here, an LDMOSFET 1) functioning as a power switching element of the power conversion circuit is formed, and an element region 2A in which a MISFET 2 configuring another circuit (for example, an information processing circuit or an analogue circuit) is formed. The withstand voltage of the transistor (here, LDMOSFET 1) formed in the element region 1A is higher than the withstand voltage of the transistor (here, MISFET 2) formed in the element region 2A. Further, the operating voltage of the transistor (here, LDMOSFET 1) formed in the element region 1A is higher than the operating voltage of the transistor (here, MISFET 2) formed in the element region 2A.

An STI region 3 (element isolation region) is formed in the upper surface SBa of the semiconductor substrate SB by an STI (Shallow Trench Isolation) method as required. The STI region 3 is formed of an insulator (insulating film) buried in a trench formed in the semiconductor substrate SB.

The semiconductor substrate SB includes an n-type substrate region KB reaching the back surface SBb of the semiconductor substrate SB, an n-type semiconductor region WL1 and a semiconductor region WL2 disposed at different positions on the n-type substrate region KB, an n-type buried layer BL formed on the n-type semiconductor region WL1 and the semiconductor region WL2, and a p-type semiconductor region EP1 and a p-type semiconductor region EP2 formed on the n-type buried layer BL and spaced apart from each other.

The n-type substrate region KB is formed of an n-type semiconductor substrate which is a base of the semiconductor substrate SB. A thickness of the n-type substrate region KB (thickness from the back surface SBb of the semiconductor substrate SB) is substantially uniform. When manufacturing the semiconductor device of the present embodiment, an n-type semiconductor substrate is used instead of a p-type semiconductor substrate.

The n-type semiconductor region WL1 is an n-type semiconductor region, and the semiconductor region WL2 is an n-type or p-type semiconductor region. That is, the conductivity type of the semiconductor region WL2 is optional. The n-type semiconductor region WL1 and the semiconductor region WL2 are formed on the n-type substrate region KB, respectively, but the n-type semiconductor region WL1 and the semiconductor region WL2 are formed at different positions on the n-type substrate region KB. Therefore, the n-type semiconductor region WL1 and the semiconductor region WL2 do not overlap with each other in plan view. The lower surface of the n-type semiconductor region WL1 is in contact with the n-type substrate region KB, and the lower surface of the semiconductor region WL2 is in contact with the upper surface of the n-type substrate region KB. The p-type semiconductor region EP1 and an n-type semiconductor region DN1 are included in the n-type semiconductor region WL1 in plan view.

The plan view corresponds to a view in a plane substantially parallel to the upper surface SBa of the semiconductor substrate SB.

In FIG. 1, the n-type semiconductor region WL1 (side surface thereof) and the semiconductor region WL2 (side surface) are adjacent to each other. When the semiconductor region WL2 is of p-type, a PN junction is formed at a boundary between the semiconductor region WL2 and the n-type semiconductor region WL1. When the semiconductor region WL2 is of n-type, both the n-type semiconductor region WL1 and the semiconductor region WL2 are n-type semiconductor regions, and no PN junction is formed between the n-type semiconductor region WL1 and the semiconductor region WL2. When the semiconductor region WL2 is of n-type, the impurity concentration (n-type impurity concentration) of the n-type semiconductor region WL1 and the impurity concentration (n-type impurity concentration) of the semiconductor region WL2 may be the same or different. Therefore, when the semiconductor region WL2 is of n-type, there may or may not be a boundary between the n-type semiconductor region WL1 and the semiconductor region WL2, and the entire combination of the n-type semiconductor region WL1 and the semiconductor region WL2 can be regarded as one n-type semiconductor region.

The n-type substrate region KB, the n-type semiconductor region WL1, and the n-type buried layer BL are of the same conductivity type (n-type). The impurity concentration (n-type impurity concentration) of the n-type semiconductor region WL1 is higher than the impurity concentration (n-type impurity concentration) of the n-type substrate region KB. The impurity concentration (n-type impurity concentration) of the n-type buried layer BL is higher than the impurity concentration (n-type impurity concentration) of the n-type semiconductor region WL1 and the impurity concentration (n-type impurity concentration) of the n-type substrate region KB, respectively.

The lower surface of the n-type buried layer BL located on the n-type semiconductor region WL1 is in contact with the upper surface of the n-type semiconductor region WL1, and the lower surface of the n-type buried layer BL located on the semiconductor region WL2 is in contact with the upper surface of the semiconductor region WL2. When the semiconductor region WL2 is of p-type, a PN junction is formed at the boundary between the n-type buried layer BL and the semiconductor region WL2, but when the semiconductor region WL2 is of n-type, a PN junction is not formed at the boundary between the n-type buried layer BL and the semiconductor region WL2.

The semiconductor substrate SB further includes an n-type semiconductor region DN that reaches the upper surface SBa of the semiconductor substrate SB from the n-type buried layer. The n-type semiconductor region DN extends from the n-type buried layer BL to the upper surface SBa of the semiconductor substrate SB in a thickness direction of the semiconductor substrate SB, the lower surface (bottom surface) of the n-type semiconductor region DN is in contact with the upper surface of the n-type buried layer BL, and the upper surface of the n-type semiconductor region DN reaches the upper surface SBa of the semiconductor substrate SB. In plan view, the n-type semiconductor region DN is interposed between the p-type semiconductor region EP1 and the p-type semiconductor region EP2. More specifically, in plan view, the n-type semiconductor region DN surrounds the p-type semiconductor region EP1. In plan view, the n-type semiconductor region DN is formed so as to surround the p-type semiconductor region EP1, but the n-type semiconductor region DN may be formed so as to surround each of the p-type semiconductor regions EP1,EP2.

In the following description, the n-type semiconductor region DN surrounding the p-type semiconductor region EP1 in plan view is referred to as the n-type semiconductor region DN1 with a symbol DN1, and the n-type semiconductor region DN other than a portion surrounding the p-type semiconductor region EP1 in plan view is referred to as an n-type semiconductor region DN2 with a symbol DN2. The n-type semiconductor region DN1 covers the side surface of the p-type semiconductor region EP1. The n-type semiconductor regions DN1,DN2 are formed so as to reach the upper surface SBa of the semiconductor substrate SB from the n-type buried layer BL, but the n-type semiconductor region DN1 is adjacent to the p-type semiconductor region EP1, but the p-type semiconductor region EP2 is not adjacent to the p-type semiconductor region EP1. The n-type semiconductor region DN1 and the n-type semiconductor region DN2 may be connected to each other or may be spaced apart from each other. In plan view, since the periphery of the p-type semiconductor region EP1 is surrounded by the n-type semiconductor region DN1, the n-type semiconductor region DN1 is interposed between the p-type semiconductor region EP1 and the p-type semiconductor region EP2 in plan view. In other words, in plan view, the p-type semiconductor region EP1 and the p-type semiconductor region EP2 are next to each other via the n-type semiconductor region DN1.

The bottom surface of the p-type semiconductor region EP1 is in contact with the n-type buried layer BL, and the side surface of the p-type semiconductor region EP1 is in contact with the n-type semiconductor region DN1. In other words, the bottom surface of the p-type semiconductor region EP1 is covered with the n-type buried layer BL, and the side surface of the p-type semiconductor region EP1 is covered with the n-type semiconductor region DN1. The bottom surface of the p-type semiconductor region EP2 is in contact with the n-type buried layer BL, and the side surface of the p-type semiconductor region EP2 is in contact with the n-type semiconductor region DN (the n-type semiconductor region DN1 or the n-type semiconductor region DN2). In other words, the bottom surface of the p-type semiconductor region EP2 is covered with the n-type buried layer BL, and the side surface of the p-type semiconductor region EP2 is covered with the n-type semiconductor region DN (the n-type semiconductor region DN1 or the n-type semiconductor region DN2).

The p-type semiconductor region EP1, the p-type semiconductor region EP2, and the n-type semiconductor region DN are formed on the n-type buried layer BL, but are formed at different positions on the n-type buried layer BL, and therefore do not overlap with each other in plan view.

The n-type buried layer BL, the n-type semiconductor region WL1, and the n-type substrate region KB are present in this order under the p-type semiconductor region EP1 and the n-type semiconductor region DN1, and the n-type buried layer BL, the semiconductor region WL2, and the n-type substrate region KB are present in this order under the p-type semiconductor region EP2. Therefore, in the semiconductor substrate SB, the region under the p-type semiconductor region EP1 and the n-type semiconductor region DN1 are all n-type, and there is no p-type semiconductor region under the p-type semiconductor region EP1 and the n-type semiconductor region DN1.

The element region 1A is included in the p-type semiconductor region EP1 in plan view, and the element region 2A is included in the p-type semiconductor region EP2 in plan view. Therefore, an n-type source region SR1, an n-type drain region DR1, and a channel forming region (the region where the channel is formed) of the LDMOSFET 1 formed in the element region 1A are formed in the p-type semiconductor region EP1 in plan view. A source region SR2, a drain region DR2, and a channel forming region of the MISFET 2 formed in the element region 2A are formed in the p-type semiconductor region EP2 in plan view.

Next, the configuration of the LDMOSFET 1 formed in the element region 1A will be described. The LDMOSFET 1 is an n-type (n-channel type) MISFET (transistor).

In the semiconductor substrate SB, an n-type semiconductor region (n-type drift layer, n-type well) ND and a p-type semiconductor region (p-type body region, p-type well) PB are formed in an upper portion (upper layer portion) of the p-type semiconductor region EP1. The n-type semiconductor region ND and the p-type semiconductor region PB are adjacent to each other in the gate length direction of the LDMOSFET 1. Note that the gate length direction of the LDMOSFET 1 corresponds to a gate length direction of a gate electrode GE1 of the LDMOSFET 1, and the gate width direction of the LDMOSFET 1 corresponds to a gate width direction of the gate electrode GE1 of the LDMOSFET 1. In the n-type semiconductor region ND and the p-type semiconductor region PB, the n-type semiconductor region ND is located on the drain side of the LDMOSFET 1, and the p-type semiconductor region PB is located on the source side of the LDMOSFET 1. The n-type semiconductor region ND and the p-type semiconductor region PB reach the upper surface SBa of the semiconductor substrate SB, respectively. The bottom surface of each of the n-type semiconductor region ND and the p-type semiconductor region PB are in contact with the p-type semiconductor region EP1. A PN junction is formed at a boundary between the n-type semiconductor region ND and the p-type semiconductor region EP1. The impurity concentration (p-type impurity concentration) of the p-type semiconductor region PB is higher than the impurity concentration (p-type impurity concentration) of the p-type semiconductor region EP1.

The p-type semiconductor region PB is formed so as to surround the n-type source region SR1 and a p-type semiconductor region PR, which will be described later. The p-type semiconductor region PB can function as a back gate. The p-type semiconductor region PB can also function as a punch-through stopper that suppresses the extension of the depletion layer from the drain to the source of LDMOSFET. Between the n-type source region SR1 and the n-type drain region DR1, an upper portion (upper layer portion) of the p-type semiconductor region PB located under the gate electrode GE1 serves as a channel forming region of the LDMOSFET.

In the semiconductor substrate SB, the n-type source region SR1 and the p-type semiconductor region PR are formed in the p-type semiconductor region PB. The n-type source region SR1 functions as a source region of the LDMOSFET 1. The impurity concentration (p-type impurity concentration) of the p-type semiconductor region PR is higher than the impurity concentration (p-type impurity concentration) of the p-type semiconductor region PB. In the gate length direction of the LDMOSFET 1, the p-type semiconductor region PR is adjacent to the n-type source region SR1. In the p-type semiconductor region PR and the n-type source region SR1, the source region SR1 is located on a side adjacent to the channel forming region of the LDMOSFET 1, and the p-type semiconductor region PR is located on a side far from the channel forming region of the LDMOSFET 1. The bottom surface of the p-type semiconductor region PB and the bottom surface of the n-type source region SR1 are in contact with the p-type semiconductor region PB. In addition, a side surface of the n-type source region SR1 opposite to the side adjacent to the p-type semiconductor region PR is in contact with the p-type semiconductor region PB. The upper surface of the p-type semiconductor region PB and the upper surface of the n-type source region SR1 reach the upper surface SBa of the semiconductor substrate SB. The p-type semiconductor region PR can function as a contact portion of the p-type semiconductor region PB.

In the n-type semiconductor region ND, the n-type drain region (n-type semiconductor region) DR1 is formed. The n-type drain region DR1 functions as a drain region of the LDMOSFET 1. The upper surface of the n-type drain region DR1 reaches the upper surface SBa of the semiconductor substrate SB. The impurity concentration (n-type impurity concentration) of the n-type drain region DR1 is higher than the impurity concentration (n-type impurity concentration) of the n-type semiconductor region ND. The n-type drain region DR1 and the n-type source region SR1 are spaced apart from each other in the gate length direction of the LDMOSFET 1.

The gate electrode GE1 of the LDMOSFET 1 is formed on the upper surface SBa of the semiconductor substrate SB via a gate dielectric film GF1. Specifically, the gate electrode GE1 is formed on the upper surface SBa of the semiconductor substrate SB between the n-type source region SR1 and the n-type drain region DR1 via the gate dielectric film GF1. The gate dielectric film GF1 is formed of, for example, a silicon oxide film. The gate electrode GE1 is formed of, for example, a single film of a polycrystalline silicon film (doped polysilicon film) or a stacked film of a polycrystalline silicon film and a metal silicide layer.

In plan view, the STI region 3 is disposed between the channel forming region of the LDMOSFET 1 and the n-type semiconductor region ND, and a part (a part of the drain-side) of the gate electrode GE1 is formed on the STI region 3. That is, a part of the gate electrode GE1 is located on the STI region 3. The n-type semiconductor region ND is present under the STI region 3 interposed between the channel forming region of the LDMOSFET 1 and the n-type semiconductor region ND. The bottom surface of the n-type drain region DR1 is in contact with the n-type semiconductor region ND, and the side surface of the n-type drain region DR1 is in contact with the STI region 3. Therefore, the n-type semiconductor region ND under the STI region 3 can also function as a conduction path between the channel and the n-type semiconductor region ND of the LDMOSFET 1.

Note that in FIG. 1, the gate dielectric film GF1 is interposed between the STI region 3 and the gate electrode GE1, but the gate dielectric film GF1 may not be interposed between the STI region 3 and the gate electrode GE1. Sidewall spacers (not shown) formed of an insulating film (for example, a silicon oxide film) may be formed on both side surfaces of the gate electrode GE1.

A part of the p-type semiconductor region PB is located under the gate electrode GE1, and a part of the n-type semiconductor region ND is located under the gate electrode GE1. A PN junction is formed at a boundary between the p-type semiconductor region PB and the n-type semiconductor region ND. This boundary is located under the middle of the gate electrode GE1 in the gate length direction of the LDMOSFET 1. This boundary is located under the gate electrode GE1 and extends in the gate width direction of the LDMOSFET 1.

In plan view, the gate electrode GE1 is disposed between the n-type source region SR1 and the n-type drain region DR1. When a voltage equal to or higher than the threshold voltage is applied to the gate electrode GE1, an n-type inversion layer is formed in the upper portion (upper layer portion) of the p-type semiconductor regions PB located under the gate electrode GE1. The n-type inversion layer serves as a channel. The n-type source region SR1 and the n-type drain region DR1 conduct via the channel and the n-type semiconductor region ND.

In the gate length direction of the LDMOSFET 1, the n-type semiconductor region ND having an impurity concentration (n-type impurity concentration) lower than that of the n-type drain region DR1 is interposed between the p-type semiconductor region PB and the n-type drain region DR1. Therefore, the n-type semiconductor region ND having an impurity concentration lower than that of the n-type drain region DR1 is present between the channel forming region of the LDMOSFET 1 and the n-type drain region DR1, and the n-type semiconductor region ND can function as an n-type drift region. Therefore, in the gate length direction of the LDMOSFET 1, the channel forming region and the n-type semiconductor region ND (n-type drift region) are present between the n-type source region SR1 and the n-type drain region DR1, the channel forming region is located on the n-type source region SR1 side, and the n-type semiconductor region ND is located on the n-type drain region DR1 side. The n-type semiconductor region ND and the p-type semiconductor region EP1 under the p-type semiconductor region PB can function as a resurf layer (resurf region).

Next, the configuration of the MISFET 2 formed in the element region 2A will be described.

In the semiconductor substrate SB, a p-type well (p-type semiconductor region) PW is formed in an upper portion (upper layer portion) of the p-type semiconductor region EP2. The p-type well PW reaches the upper surface SBa of the semiconductor substrate SB. The bottom surface of the p-type well PW is in contact with the p-type semiconductor region EP2. The impurity concentration (p-type impurity concentration) of the p-type well PW is higher than the impurity concentration (p-type impurity concentration) of the p-type semiconductor region EP2.

In the semiconductor substrate SB, the n-type source region SR2 and the n-type drain region DR2 are formed in the p-type well PW. The n-type source region SR2 functions as a source region of the MISFET 2, and the n-type drain region DR2 functions as a drain region of the MISFET 2. The n-type drain region DR2 and the n-type source region SR2 are spaced apart from each other in the gate length direction of the MISFET 2. Note that the gate length direction of the MISFET 2 corresponds to a gate length direction of a gate electrode GE2 of the MISFET 2, and the gate width direction of the MISFET 2 corresponds to the gate width direction of the gate electrode GE2 of the MISFET 2. The upper surface of each of the n-type source region SR2 and the n-type drain region DR2 reaches the upper surface SBa of the semiconductor substrate SB. Each bottom surface and each side surface of the n-type source region SR2 and the n-type drain region DR2 are in contact with the p-type well PW.

The gate electrode GE2 is formed on the upper surface SBa of the semiconductor substrate SB between the n-type source region SR2 and the n-type drain region DR2 (i.e., on the p-type well PW) via a gate dielectric film GF2. The gate dielectric film GF2 is formed of, for example, a silicon oxide film. The gate electrode GE2 is formed of, for example, a single film of a polycrystalline silicon film (doped polysilicon film) or a stacked film of a polycrystalline silicon film and a metal silicide layer. Sidewall spacers (not shown) formed of an insulating film (for example, a silicon oxide film) may be formed on both side surfaces of the gate electrode GE2.

In the present embodiment, a DTI (Deep Trench Isolation) region 4 is formed in the semiconductor substrate SB. The DTI region 4 is formed of an insulator (insulating film) buried in a trench formed in the semiconductor substrate SB. The depth of the DTI region 4 is greater than the depth of the STI region 3. That is, the depth position of the bottom surface of the DTI region 4 is deeper than the depth of the bottom surface of the STI region 3. In FIG. 1, the bottom surface of the DTI region 4 is located in the middle of the thickness of the semiconductor regions WL1,WL2.

In plan view, the DTI region 4 is disposed so as to surround the element region 1A, and the DTI region 4 is disposed so as to surround the element region 2A. The DTI region 4 disposed so as to surround the element region 1A penetrates through the p-type semiconductor region EP1 and the n-type buried layer BL under the p-type semiconductor region EP1, and reaches the semiconductor region WL1, and the bottom surface of the DTI region 4 is located in the middle of the thickness of the semiconductor region WL1. Further, the DTI region 4 disposed so as to surround the element region 2A penetrates through the p-type semiconductor region EP2 and the n-type buried layer BL under the p-type semiconductor region EP2, and reaches the semiconductor region WL2, and the bottom surface of the DTI region 4 is located in the middle of the thickness of the semiconductor region WL2. The DTI region 4 disposed so as to surround the element region 1A has a function of electrically isolating the element region 1A, the DTI region 4 disposed so as to surround the element region 2A has a function of electrically isolating the element region 2A.

In addition, a metal silicide layer (not shown) may be formed on each of the upper portions (surface layer portions) of the n-type drain region DR1, the n-type source region SR1, the p-type semiconductor region PR, the n-type semiconductor region DN (particularly, the n-type semiconductor region DN1), the n-type drain region DR2, and the n-type source region SR2. The metal silicide layers can be formed using a Salicide (Self Aligned Silicide) technique.

Next, the structure on the semiconductor substrate SB will be described.

An interlayer dielectric film IL is formed as a dielectric film on the upper surface SBa of the semiconductor substrate SB so as to cover the gate electrodes GE1,GE2. The interlayer dielectric film IL is formed of, for example, a silicon oxide film. The interlayer dielectric film IL can also be formed by a stacked film of a relatively thin silicon nitride film and a relatively thick silicon oxide film on the silicon nitride. An upper surface of the interlayer dielectric film IL is planarized.

A contact hole (through-hole) is formed in the interlayer dielectric film IL, and a conductive plug (contact plug) PG including a tungsten (W) film as a main component is formed (buried) in the contact hole. A plurality of plugs PG are provided, and each of the plurality of plugs PG penetrates through the interlayer dielectric film IL. The plug PG is formed on each of the n-type source region SR1, the n-type drain region DR1, the p-type semiconductor region PR, the n-type semiconductor region DN1, the n-type source region SR2, and the n-type drain region DR2.

Here, the plug PG disposed on the n-type drain region DR1 and electrically connected to the n-type drain region DR1 is referred to as a plug PGD. The plug PG disposed on the n-type semiconductor region DN1 and electrically connected to the n-type semiconductor region DN1 is referred to as a plug PGN.

The plug PG may also be disposed on each of the gate electrodes GE1,GE2, but the plugs PG on the gate electrodes GE1,GE2 are not shown in cross-sectional view of FIG. 1.

The plug PG disposed on the n-type drain region DR1 is electrically connected to the n-type drain region DR1 by being in contact with the n-type drain region DR1. The plug PG disposed on the n-type source region SR1 is electrically connected to the n-type source region SR1 by being in contact with the n-type source region SR1. The plug PG disposed on the p-type semiconductor region PR is electrically connected to the p-type semiconductor region PR by being in contact with the p-type semiconductor region PR, and is further electrically connected to the p-type semiconductor region PB via the p-type semiconductor region PR. The plug PGN disposed on the n-type semiconductor region DN1 is electrically connected to the n-type semiconductor region DN1 by being in contact with the n-type semiconductor region DN1. The plug PG disposed on the n-type source region SR2 is electrically connected to the n-type source region SR2 by being in contact with the n-type source region SR2. The plug disposed on the n-type drain region DR2 is electrically connected to the n-type drain region DR2 by being in contact with the n-type drain region DR2.

When a metal silicide layer (not shown) is formed on each of the upper portions (surface layer portions) of the n-type drain region DR1, the n-type source region SR1, the p-type semiconductor region PR, the n-type semiconductor region DN1, the n-type drain region DR2, and the n-type source region SR2, each plug PG is in contact with the metal silicide layer and is electrically connected to each region under the metal silicide layer via the metal silicide layer.

Wirings (first layer wirings) M1 formed of a conductive film mainly formed of aluminum (Al), aluminum alloy, or the like are formed on the interlayer dielectric film IL in which the plug PG is buried. The wirings M1 are preferably aluminum wirings, but may also be wirings using other metal materials, for example, tungsten wirings or copper wirings. Each of the plugs PG is electrically connected to the wiring M1.

The wirings M1 include a source wiring M1S electrically connected to the n-type source region SR1 via the plug PG, a drain wiring M1D electrically connected to the n-type drain region DR1 via the plug PGD, and a wiring M1N electrically connected to the n-type semiconductor region DN1 via the plug PGN.

The source wiring M1S is electrically connected to the p-type semiconductor region PR via the plug PG disposed on the p-type semiconductor region PR. That is, the source wiring M1S is electrically connected to both the plug PG disposed on the n-type source region SR1 and the plug PG disposed on the p-type semiconductor region PR. Therefore, the potential supplied from the plug PG disposed on the n-type source region SR1 to the n-type source region SR1 and the potential supplied from the plug PG disposed on the p-type semiconductor region PR to the p-type semiconductor region PR are the same as each other. Therefore, the potential which is the same as the potential (source potential) supplied from the source wiring M1S to the n-type source region SR1 via the plug PG (the plug PG disposed on the n-type source region SR) is supplied from the source wiring M1S to the p-type semiconductor region PR via the plug PG (the plug PG disposed on the p-type semiconductor region PR), and further supplied from the p-type semiconductor region PR to the p-type semiconductor region PB.

The wirings M1 also include a wiring electrically connected to the n-type source region SR2 via the plug PG and a wiring electrically connected to the n-type drain region DR2 via the plug PG. The wirings M1 further include a gate wiring electrically connected to the gate electrode GE1 via the plug PG and a gate wiring electrically connected to the gate electrode GE2 via the plug PG, but the gate wirings are not shown in cross-sectional view of FIG. 1.

The interlayer dielectric film IL and a structure above the wirings M1 are not shown and described here.

In addition, the LDMOSFET 1 formed in the element region 1A may have a configuration in which a plurality of LDMOSFETs are connected in parallel. The MISFET 2 formed in the element region 2A may be singular or plural.

In the present embodiment, the n-channel type MISFET 2 is formed in the element region 2A, but a p-channel type MISFET may be formed in the element region 2A instead of the n-channel type MISFET 2. In such case, the p-type well PW becomes an n-type well, and the n-type source region SR2 and the n-type drain region DR2 becomes a p-type source region and a p-type drain region. In addition, both an n-channel MISFET and a p-channel MISFET can be formed in the element region 2A.

### BACKGROUND OF CONSIDERATION

FIG. 3 is a circuit diagram showing an exemplary inverter circuit INV of the power conversion circuit.

The inverter circuit INV shown in FIG. 3 includes a power transistor (high-side transistor) TR1 and a power transistor (low-side transistor) TR2 connected in series. The power transistors TR1,TR2 are power switching elements, the power transistor TR1 is a transistor for a high-side switch (high-potential-side switch), and the power transistor TR2 is a transistor for a low-side switch (low-potential-side switch). The LDMOSFET 1 included in the semiconductor device of the present embodiment can be used as the power transistor TR1 or the power transistor TR2.

The power transistor TR1 and the power transistor TR2 are connected in series between a terminal T1 and a terminal T2, a drain (D1) of the power transistor TR1 is connected to the terminal T1, a source (S1) of the power transistor TR1 is connected to a drain (D2) of the power transistor TR2, and a source (S2) of the power transistor TR2 is connected to the terminal T2. A terminal T3 is electrically connected to both the source (S1) of the power transistor TR1 and the drain (D2) of the power transistor TR2. A power supply potential (VIN) is supplied from a power supply (battery) or the like to the terminal T1. A reference potential lower than the power supply potential, for example, a ground potential (GND) is supplied to the terminal T2. The terminal T3 is a terminal for outputting. The terminal T3 is connected to load, and is connected to a coil CL used in, for example, a motor.

A gate (G1) of the power transistor TR1 and a gate (G2) of the power transistor TR2 are connected to a driving circuit, and a gate voltage is supplied from the driving circuit to the gates (G1,G2) of the power transistors TR1,TR2. The operation of the power transistors TR1,TR2 can be controlled by controlling the gate voltage supplied to the gate (G1) of the power transistor TR1 and the gate voltage supplied to the gate (G2) of the power transistor TR2.

Here, a part of the operation of the inverter circuit INV shown in FIG. 3 will be described.

When the inverter circuit INV is in the standby state, the gate voltage of the power transistor TR1 and the gate voltage of the power transistor TR2 are lower than the threshold voltage (e.g., 0V), so that both of the power transistors TR1,TR2 are in the off-state (non-conductive state), and no current flows through the coil CL.

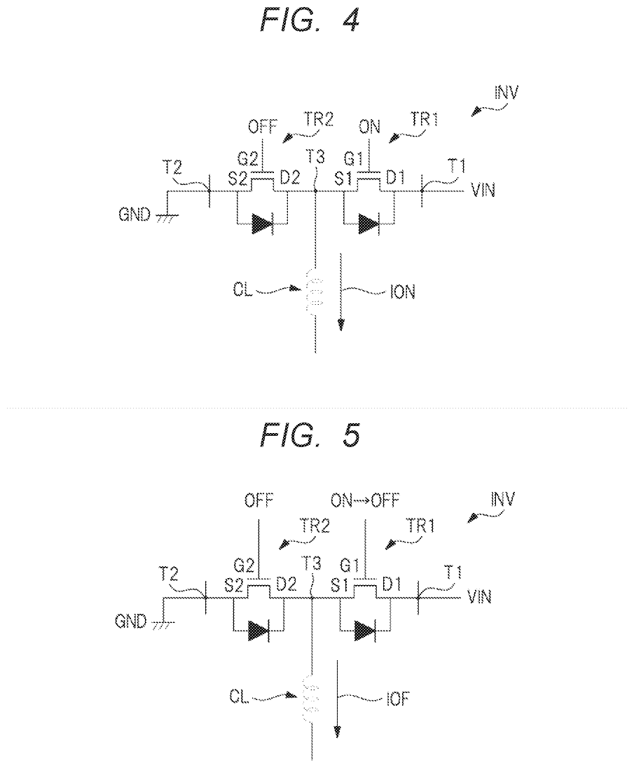

Next, when the gate voltage of the power transistor TR2 is kept lower than the threshold voltage (for example, 0V) and a gate voltage equal to or higher than the threshold voltage is supplied to the gate (G1) of the power transistor TR1, the power transistor TR1 is turned on (conductive state) and the power transistor TR2 is turned off (non-conductive state). The circuit diagram of FIG. 4 shows this state. In this state (FIG. 4), a current ION flows from the terminal T1 to which the power supply voltage VIN is supplied to the coil CL through the power transistor TR1 and the terminal T3.

Next, it is considered that the gate voltage of the power transistor TR2 is kept lower than the threshold voltage (e.g., 0V), and the gate voltage of the power transistor TR1 is reduced from a voltage equal to or higher than the threshold voltage to a voltage lower than the threshold voltage (e.g., 0V). In this case, the power transistor TR1 is turned on, and the power transistor TR2 is turned off, and then the power transistors TR1,TR2 are both turned off. At this time, an electromotive force that suppresses a change in the magnetic flux density of the coil CL acts, and a transient state occurs in which the terminal T3 has a negative potential and a current IOF flows from the terminal T3 to the coil CL. The circuit diagram of FIG. 5 shows this transient state. This transient state (a state in which the terminal T3 is at a negative potential) is settled and eliminated by the passage of time. That is, this transient state (a state in which the terminal T3 is at a negative potential) temporarily occurs when the state of the power transistor TR1 is changed from on-state to off-state while remaining the state of the power transistor TR2 in off-state. The source of the current IOF flowing in the coil CL is configured of a current flowing from the terminal T2 through a parasitic diode formed in the power transistor TR2 to the terminal T3 and a current supplied from the semiconductor substrate on which the power transistor TR2 is formed to the terminal T3. That is, in the transient state (the state in which the terminal T3 is at a negative potential) shown in FIG. 5, in the semiconductor substrate where the power transistor TR2 is formed, electrons are injected from the drain (D2) of the power transistor TR2 to the semiconductor substrate, reflecting that a current is supplied from the semiconductor substrate in which the power transistor TR2 is formed to the terminal T3.

The transient state (a state in which the terminal T3 is at a negative potential) corresponds to a state in which the source (S2) of the power transistor TR2 is at a ground potential (GND) and the drain (D2) of the power transistor TR2 is at a negative potential. When the LDMOSFET 1 of the semiconductor device of the present embodiment is used as the power transistor TR2, the drain region (n-type drain region DR1) of the LDMOSFET 1 has a negative potential in the transient state (a state where the terminal T3 has a negative potential) shown in FIG. 5.

When the drain region (n-type drain region DR1) of the LDMOSFET 1 has a negative potential, electrons are injected into the semiconductor substrate SB from the drain region. In other words, reflecting the injection of electrons from the n-type drain region DR1 into the semiconductor substrate SB, holes move from the n-type drain region DR1 to the plug PGD1, and further move through the drain wiring M1D or the like to the terminal T3 outside the semiconductor device, so that the current IOF can flow from the terminal T3 to the coil CL.

It is undesirable that an adverse effect occurs in the MISFET 2 formed in the element region 2A due to the injection of electrons from the drain region (n-type drain region DR1) of the LDMOSFET 1 into the semiconductor substrate SB when the drain region (n-type drain region DR1) of the LDMOSFET 1 has a negative potential, because the performance of the semiconductor device is degraded.

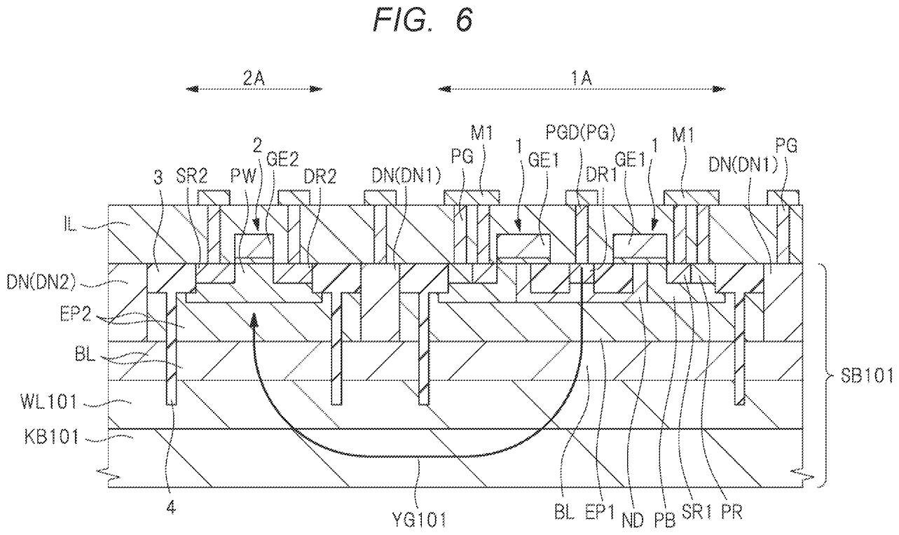

FIG. 6 is a cross-sectional view of the semiconductor device of the examined example studied by the present inventor, and shows a cross section corresponding to FIG. 1.

In the examined example shown in FIG. 6, a semiconductor substrate SB101 corresponding to the semiconductor substrate SB is different from the semiconductor substrate SB in the following points.

That is, although the semiconductor substrate SB101 configuring the semiconductor device of the examined example shown in FIG. 6 has a p-type substrate region KB101 corresponding to the n-type substrate region KB, the p-type substrate region KB101 is p-type instead of n-type. The p-type substrate region KB101 is formed by a semiconductor substrate that serves as a base for the semiconductor substrate SB101.

Therefore, when the semiconductor device of the examined example of FIG. 6 is manufactured, a p-type semiconductor substrate is used. In the semiconductor substrate SB101 of the examined example, the p-type semiconductor region WL101 between the p-type substrate region KB101 and the n-type buried layer BL is not n-type but p-type. In the examined example of FIG. 6, the n-type semiconductor region WL1 and the semiconductor region WL2 together form a p-type semiconductor region WL101. The impurity concentration (p-type impurity concentration) of the p-type semiconductor region WL101 is lower than the impurity concentration (p-type impurity concentration) of the p-type substrate region KB101. The structure of the n-type buried layer BL and above the n-type buried layer BL in the semiconductor substrate SB101 of FIG. 6 is substantially the same as those in the semiconductor substrate SB of FIG. 1, therefore repetitive explanation thereof will be omitted here.

Therefore, in FIG. 6, in the semiconductor substrate SB101, the n-type buried layer BL, the p-type semiconductor region WL101, and the p-type substrate region KB101 are present in this order under the p-type semiconductor region EP1 and the n-type semiconductor region DN1. In the semiconductor substrate SB101 of FIG. 6, the n-type buried layer BL, the p-type semiconductor region WL101, and the p-type substrate region KB101 are present in this order under the p-type semiconductor region EP2. Therefore, in FIG. 6, in the semiconductor substrate SB101, the n-type buried layer BL is present under the p-type semiconductor region EP1 and the n-type semiconductor region DN1, and further, the p-type region (the p-type semiconductor region WL101 and the p-type substrate region KB101) instead of n-type region is present under the n-type buried layer BL.

Here, the problem of the semiconductor device of the examined example of FIG. 6 will be described.

As described with reference to FIGS. 2 to 4, when the LDMOSFET 1 formed in the element region 1A is used as the power transistor TR2 for the low-side switch, the drain region (n-type drain region DR1) of the LDMOSFET 1 may have a negative potential. When the n-type drain region DR1 has a negative potential, electrons are injected from the n-type drain region DR1 into the semiconductor substrate SB101, but the injected electrons are injected through the p-type semiconductor region EP1 into the n-type buried layer BL under the p-type semiconductor region EP1, and further electrons are injected from the n-type buried layer BL into the p-type semiconductor region WL101 and the p-type substrate region KB101 under the n-type buried layer BL. When the n-type drain region DR1 has a negative potential, the n-type buried layer BL under the p-type semiconductor region EP1 also tends to have a negative potential due to the effect thereof, and this also promotes the phenomena in which electrons are injected from the n-type buried layer BL under the p-type semiconductor region EP1 into the p-type semiconductor region WL101 and the p-type substrate region KB101 under the n-type buried layer BL. In the p-type semiconductor region, holes are majority carriers and electrons are minority carriers. Therefore, when electrons are injected from the n-type buried layer BL under the p-type semiconductor region EP1 into the p-type region (the p-type semiconductor region WL101 and the p-type substrate region KB101) below under the n-type buried layer BL, the injected electrons behave as minority carriers, and thus can move in the p-type region by diffusion until they recombine with holes and disappear. Therefore, when electrons are injected from the n-type buried layer BL under the p-type semiconductor region EP1 into the p-type region (the p-type semiconductor region WL101 and the p-type substrate region KB101) under the n-type buried layer BL, the injected electrons may move considerably in the p-type region (the p-type semiconductor region WL101 and the p-type substrate region KB101) under the n-type buried layer BL. Consequently, electrons may move in the p-type region (the p-type semiconductor region WL101 and the p-type substrate region KB101) under the n-type buried layer BL to a position under the p-type semiconductor region EP2, and may be injected through the n-type buried layer BL into the p-type semiconductor region EP2. That is, in FIG. 6, when the drain region (n-type drain region DR1) of the LDMOSFET 1 has a negative potential, electrons are injected from the drain region into the semiconductor substrate SB, and there is a possibility that the electrons move along the path in the arrow YG101 in FIG. 6 and are injected into the p-type semiconductor region EP2. It is not desirable that the electrons move along the path in the arrow YG101 in FIG. 6 and are injected into the p-type semiconductor region EP2, which may affect the characteristics of the MISFET 2 formed in the element region 2A, leading to degradation of the performance of semiconductor device.

Therefore, when the drain region (n-type drain region DR1) of the LDMOSFET 1 has a negative potential, in order to prevent the electrons from moving in the path in the arrow YG101 in FIG. 6 and being injected into the p-type semiconductor region EP2, it is conceivable to increase the distance between the element region 1A and the element region 2A. As the distance between the element region 1A and the element region 2A increases, when the drain region (n-type drain region DR1) of the LDMOSFET 1 has a negative potential, the probability that electrons move in the path in the arrow YG101 of FIG. 6 and are injected into the p-type semiconductor region EP2 decreases. However, increasing the distance between the element region 1A and the element region 2A is undesirable because it increases the planar dimension of the semiconductor device and leads to an increase in the size of the semiconductor device.

Therefore, without increasing the distance between the element region 1A and the element region 2A, when the drain region (n-type drain region DR1) of the LDMOSFET 1 has a negative potential, it is desired to prevent electrons from moving in the path in the arrow YG101 of FIG. 6 and being injected into the p-type semiconductor region EP2.

### MAIN FEATURES AND EFFECTS

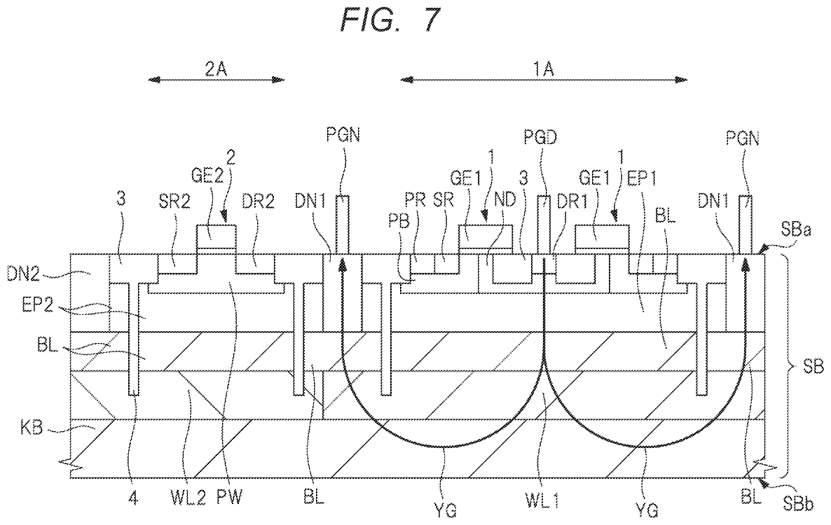

FIG. 7 is an explanatory diagram of the semiconductor device of the present embodiment. FIG. 7 shows the same cross-section as that of FIG. 1, but the illustration of the interlayer dielectric film IL and the wirings M1 is omitted in FIG. 7 for simplicity. In addition, in FIG. 7, the plugs PG other than the plugs PGD,PDN are omitted. In addition, in FIG. 7, only the n-type substrate region KB, the n-type semiconductor region WL1, and the n-type buried layer BL are hatched, and hatching is omitted otherwise.

The semiconductor device of the present embodiment can be used in the power conversion circuit having a high-side transistor (the power transistor TR1) and a low-side transistor (the power transistor TR2) connected in series. The LDMOSFET 1 formed in the element region 1A can be used as the low-side transistor (the power transistor TR2) or the high-side transistor (the power transistor TR2), but in particular, when used as the low-side transistor (the power transistor TR2), there is a concern that the problem described with respect to the examined example of FIG. 6 may occur.

As described with reference to FIGS. 3 to 5, when the LDMOSFET 1 formed in the element region 1A is used as the power transistor TR2 for the low-side switch, the drain region (n-type drain region DR1) of the LDMOSFET 1 may have a negative potential. When the drain region (n-type drain region DR1) of the LDMOSFET 1 has a negative potential, electrons are injected from the drain region (n-type drain region DR1) into the semiconductor substrate SB.

It is undesirable that an adverse effect occurs in the MISFET 2 formed in the element region 2A due to the injection of electrons from the drain region (n-type drain region DR1) of the LDMOSFET 1 into the semiconductor substrate SB, because the performance of the semiconductor device is degraded. In the present embodiment, even if electrons are injected from the drain region (n-type drain region DR1) to the semiconductor substrate SB when the drain region (n-type drain region DR1) of the LDMOSFET 1 has a negative potential, the MISFET 2 formed in the element region 2A of the semiconductor substrate SB is not adversely affected.

In the present embodiment, as shown in FIGS. 1 and 7, in the semiconductor substrate SB configuring the semiconductor device, the n-type buried layer BL, the n-type semiconductor region WL1, and the n-type substrate region KB are present in this order under the p-type semiconductor region EP1 and the n-type semiconductor region DN1. Therefore, in the semiconductor substrate SB, the region under the p-type semiconductor region EP1 and the n-type semiconductor region DN1 is formed of all n-type regions (n-type regions including the n-type buried layer BL, the n-type semiconductor region WL1, and the n-type substrate region KB).

When the drain region (n-type drain region DR1) of the LDMOSFET 1 has a negative potential, electrons are injected from the drain region into the semiconductor substrate SB, and the injected electrons are injected through the p-type semiconductor region EP1 into an n-type region (an n-type region including the n-type buried layer BL, the n-type semiconductor region WL1, and the n-type substrate region KB) under the p-type semiconductor region EP1. In an n-type semiconductor region, holes are minority carriers and electrons are majority carriers. Electrons injected into the n-type region behave as majority carriers, and therefore, when a potential gradient is generated in the n-type region, the electrons tend to move in accordance with the potential gradient.

In the present embodiment, a higher potential (specifically, a positive potential) than the p-type semiconductor region EP1 is applied from the plug PGN to the n-type semiconductor region DN1. Here, the p-type semiconductor region PR and the p-type semiconductor region PB are adjacent to each other, and the p-type semiconductor region PB and the p-type semiconductor region EP1 are adjacent to each other, so that the p-type semiconductor region PR, the p-type semiconductor region PB, and the p-type semiconductor region EP1 are electrically connected to each other. Therefore, the potential supplied to the p-type semiconductor region PR from the plug PG disposed on the p-type semiconductor region PR is also supplied to the p-type semiconductor region PB and the p-type semiconductor region EP1. Since the potential supplied to the p-type semiconductor region PR from the plug PG disposed on the p-type semiconductor region PR is the ground potential (0V), the potentials of both the p-type semiconductor region PB and the p-type semiconductor region EP1 are substantially the ground potential (0V). On the other hand, a positive potential is applied from the plug PGN to the n-type semiconductor region DN1. Consequently, a higher potential than the p-type semiconductor region EP1 is applied from the plug PGN to the n-type semiconductor region DN1.

A higher potential (specifically, a positive potential) than the p-type semiconductor region EP1 is applied from the plug PGN to the n-type semiconductor region DN1. As a result, a potential gradient is generated in an n-type region under the p-type semiconductor region EP1 (an n-type region formed of the n-type buried layer BL, the n-type semiconductor region WL1, and the n-type substrate region KB), in an n-type region under the n-type semiconductor region DN1 (an n-type region formed of the n-type buried layer BL, the n-type semiconductor region WL1, and the n-type substrate region KB), and in the n-type semiconductor region DN1. The potential gradient gradually increases toward the plug PGN. In the n-type region, since electrons that are majority carriers move according to the electron gradient, when the drain region (n-type drain region DR1) of the LDMOSFET 1 has a negative potential, electrons injected from the drain region into the semiconductor substrate SB move in a path indicated by an arrow YG in FIG. 7 and are discharged from the n-type semiconductor region DN1 to the plug PGN. That is, electrons injected from the drain region of the LDMOSFET 1 through the p-type semiconductor region EP1 into the n-type buried layer BL under the p-type semiconductor region EP1 move in the n-type region formed of the n-type semiconductor region WL1 and the n-type substrate region KB so as to approach the n-type semiconductor region DN1 in accordance with the potential gradient, further move in the n-type buried layer BL and the n-type semiconductor region DN1 (toward the upper surface SBa of the semiconductor substrate SB) in the thickness direction of the semiconductor substrate SB, and are discharged out of the semiconductor substrate SB from the plug PGN.

Therefore, electrons injected into the n-type buried layer BL under the p-type semiconductor region EP1 from the drain region (n-type drain region DR1) of the LDMOSFET 1 through the p-type semiconductor region EP1 move to the n-type semiconductor region DN1 only through the n-type region without passing through the p-type region, and can be discharged from the n-type semiconductor region DN1 to the plug PGN. Therefore, when the drain region of the LDMOSFET 1 has a negative potential, electrons injected from the drain region into the semiconductor substrate SB can be accurately discharged from the n-type semiconductor region DN1 to the plug PGN, and consequently, electrons injected from the drain region of the LDMOSFET 1 into the semiconductor substrate SB do not reach the semiconductor region WL2 or the p-type semiconductor region EP2. Therefore, even if electrons are injected from the drain region into the semiconductor substrate SB when the drain region of the LDMOSFET 1 has a negative potential, the characteristics of the MISFET 2 formed in the element region 2A of the semiconductor substrate SB is not affected. Therefore, the performance of the semiconductor device can be improved.

In the examined example of FIG. 6, when the drain region of the LDMOSFET 1 has a negative potential, electrons injected from the drain region into the semiconductor substrate SB are injected into the n-type buried layer EP1 under the p-type semiconductor region EP1 and further injected from the n-type buried layer BL into the p-type region (p-type semiconductor region WL101 and p-type substrate region KB101) under the n-type buried layer BL, so that the electrons diffuse in the p-type region as minority carriers. Therefore, even if a potential gradient is generated in the p-type region (the p-type semiconductor region WL101 and the p-type substrate region KB101), electrons relatively easily move randomly in the p-type region. Therefore, in the examined example of FIG. 6, when the drain region of the LDMOSFET 1 has a negative potential, it is difficult to sufficiently discharge electrons injected from the drain region into the semiconductor substrate SB from the n-type semiconductor region DN1 to the plug PGN.

On the other hand, in the present embodiment, electrons injected from the drain region (n-type drain region DR1) of the LDMOSFET 1 through the p-type semiconductor region EP1 into the n-type buried layer BL under the p-type semiconductor region EP1 are discharged from the n-type semiconductor region DN1 to the plug PGN only through the n-type region without passing through the p-type region, so that the electrons can move in the n-type region as majority carriers according to the potential gradient. Therefore, electrons injected from the drain region of the LDMOSFET 1 into the semiconductor substrate SB can be accurately discharged from the n-type semiconductor region DN1 to the plug PGN.

Further, in the present embodiment, electrons injected from the drain region of the LDMOSFET 1 into the semiconductor substrate SB can be accurately discharged from the n-type semiconductor region DN1 to the plug PGN, so that the distance between the element region 1A and the element region 2A can be reduced. Therefore, it is possible to reduce the size (area reduction) of the semiconductor device.

In the present embodiment, even if the distance between the element region 1A and the element region 2A is not increased, when the drain region of the LDMOSFET 1 has a negative potential, electrons injected from the drain region of the LDMOSFET 1 into the semiconductor substrate SB can be prevented from moving in the semiconductor substrate SB and being injected into the p-type semiconductor region EP2. Therefore, it is possible to achieve both performance improvement and miniaturization (reduction in area) of the semiconductor device.

In plan view, the n-type semiconductor region DN1 is interposed between the p-type semiconductor region EP1 and the p-type semiconductor region EP2. In plan view, the n-type semiconductor region DN1 is interposed between the element region 1A and the element region 2A. Therefore, in plan view, the n-type semiconductor region DN1 is present in the middle of the path from the p-type semiconductor region EP1 (element region 1A) to the p-type semiconductor region EP2 (element region 2A). Accordingly, when the drain region of the LDMOSFET 1 has a negative potential, electrons injected from the drain region of the LDMOSFET 1 into the semiconductor substrate SB can be prevented from moving in the semiconductor substrate SB and being injected into the p-type semiconductor region EP2.

Further, in plan view, the plug PGN is preferably disposed between the p-type semiconductor region EP1 and the p-type semiconductor region EP2. Further, in plan view, it is preferable that the plug PGN is disposed between the element region 1A and the element region 2A. As a result, in plan view, the plug PGN that functions as an electron discharge unit (extraction unit) is present in the middle of a path from the p-type semiconductor region EP1 to the p-type semiconductor region EP2. Thus, when the drain region of the LDMOSFET 1 has a negative potential, electrons injected from the drain region of the LDMOSFET 1 into the semiconductor substrate SB can be accurately prevented from being injected into the p-type semiconductor region EP2 by moving in the semiconductor substrate SB.

Further, in plan view, the n-type semiconductor region DN1 more preferably surrounds the p-type semiconductor region EP1, that is, the n-type semiconductor region DN1 more preferably surrounds the element region 1A. Thus, even if the p-type semiconductor region EP2 (element region 2A) is disposed at any position in the semiconductor substrate SB, the n-type semiconductor region DN1 is interposed between the p-type semiconductor region EP1 (element region 1A) and the p-type semiconductor region EP2 (element region 2A) in plan view. As a result, when the drain region (n-type drain region DR1) of the LDMOSFET 1 has a negative potential, electrons injected from the drain region of the LDMOSFET 1 into the semiconductor substrate SB can be prevented from moving in the semiconductor substrate SB and being injected into the p-type semiconductor region EP2 more accurately. In the semiconductor substrate SB, since the p-type semiconductor region EP1 (element region 1A) and the p-type semiconductor region EP2 (element region 2A) can be efficiently disposed, the flexibility of designing can be improved, and the semiconductor device can be advantageously miniaturized (area reduction).

Further, a positive potential is applied from the plug PGN to the n-type semiconductor region DN1, but it is more preferable that the applied voltage from the plug PGN to the n-type semiconductor region DN1 is equal to or higher than 5 V. The voltage applied from the plug PGN to the n-type semiconductor region DN1 may be the power supply potential VIN. As a result, since the voltage applied from the plug PGN to the n-type semiconductor region DN1 can be increased, the effect of discharging the electrons injected from the drain region of the LDMOSFET 1 into the semiconductor substrate SB from the n-type semiconductor region DN1 to the plug PGN can be enhanced.

### Second Embodiment

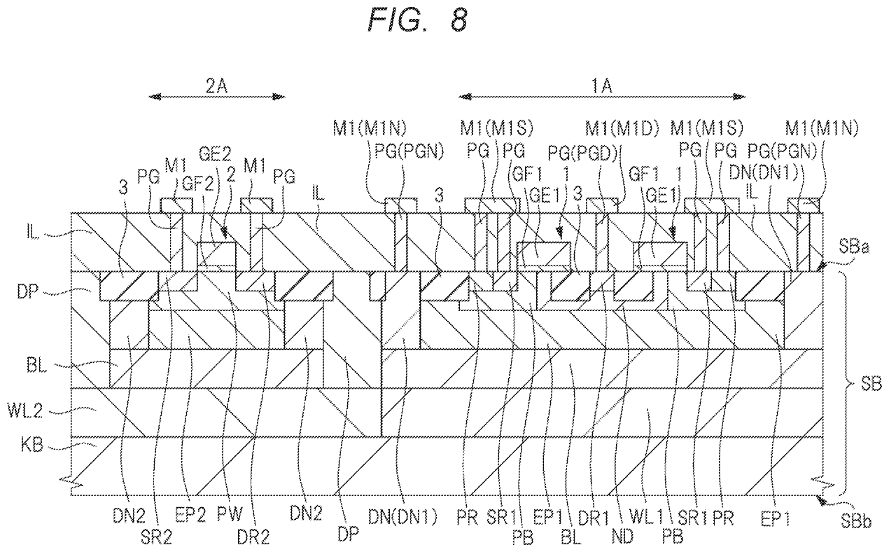

FIG. 8 is a cross-sectional view of the main portion of the semiconductor device of the second embodiment and shows a cross-section corresponding to FIG. 1.

The semiconductor device of the second embodiment shown in FIG. 8 is different from the semiconductor device of the first embodiment (FIGS. 1 and 7) in the following points.

That is, in the present second embodiment, the DTI region 4 is not formed in the semiconductor substrate SB. In the present second embodiment, in the semiconductor substrate SB, the n-type semiconductor region DN1 is formed so as to surround the p-type semiconductor region EP1 in plan view, the n-type semiconductor region DN2 is formed so as to surround the p-type semiconductor region EP2 in plan view, and a p-type semiconductor region DP is disposed between the n-type semiconductor region DN1 and the n-type semiconductor region DN2. Therefore, the bottom surface of the p-type semiconductor region EP1 is covered with the n-type buried layer BL, the side surface of the p-type semiconductor region EP1 is covered with the n-type semiconductor region DN1, the bottom surface of the p-type semiconductor region EP2 is covered with the n-type buried layer BL, and the side surface of the p-type semiconductor region EP2 is covered with the n-type semiconductor region DN2. Between the p-type semiconductor region EP1 and the p-type semiconductor region EP2, the n-type semiconductor region DN1, the p-type semiconductor region DP, and the n-type semiconductor region DN2 are disposed in this order, and the p-type semiconductor region DP is interposed between the n-type semiconductor region DN1 and the n-type semiconductor region DN2. The n-type semiconductor region DN2 reaches the bottom surface of the STI region 3.

The p-type semiconductor region DP penetrates through the n-type buried layer BL and reaches the semiconductor region WL2. That is, the n-type buried layer BL under the p-type semiconductor region EP1 and the n-type buried layer BL under the p-type semiconductor region EP2 are spaced apart from each other, and a part (lower part) of the p-type semiconductor region DP is interposed between the n-type buried layer BL under the p-type semiconductor region EP1 and the n-type buried layer BL under the p-type semiconductor region EP2. The p-type semiconductor region DP reaches from the semiconductor region WL2 to the upper surface SBa of the semiconductor substrate SB and extends in the thickness direction of the semiconductor substrate SB. The lower surface (bottom surface) of the p-type semiconductor region DP reaches the upper surface of the semiconductor region WL2, and the upper surface of the p-type semiconductor region DP reaches the upper surface SBa of the semiconductor substrate SB. In the first embodiment, the conductivity type of the semiconductor region WL2 is optional, but in the present second embodiment, the conductivity type of the semiconductor region WL2 is p-type.

Other configurations of the semiconductor device of the second embodiment are substantially the same as those of the semiconductor device of the first embodiment, and therefore, repeated explanation thereof will be omitted here.

In the present second embodiment, even if the DTI region 4 is not formed in the semiconductor substrate SB, the LDMOSFET 1 formed in the element region 1A and the MISFET 2 formed in the element region 2A can be electrically separated by the PN junction isolation.

Similarly to the above first embodiment, also in the present second embodiment, in the semiconductor substrate SB configuring the semiconductor device, the n-type buried layer BL, the n-type semiconductor region WL1, and the n-type substrate region KB are present in this order under the p-type semiconductor region EP1 and the n-type semiconductor region DN1. Therefore, in the semiconductor substrate SB, the regions under the p-type semiconductor region EP1 and the n-type semiconductor region DN1 are all n-type regions (n-type regions formed of the n-type buried layer BL, the n-type semiconductor region WL1, and the n-type substrate region KB). Accordingly, when the drain region (n-type drain region DR1) of the LDMOSFET 1 has a negative potential, electrons injected from the drain region (n-type drain region DR1) of the LDMOSFET 1 through the p-type semiconductor region EP1 into the n-type buried layer BL under the p-type semiconductor region EP1 pass through only the n-type region without passing through the p-type region, and are discharged from the n-type semiconductor region DN1 to the plug PGN. In this case, the electrons can move in the n-type region as majority carriers according to the potential gradient. Therefore, electrons injected from the drain region of the LDMOSFET 1 into the semiconductor substrate SB can be accurately discharged from the n-type semiconductor region DN1 to the plug PGN. Consequently, the performance of semiconductor device can be improved. In addition, it is possible to reduce the size (area reduction) of the semiconductor device.

### Third Embodiment

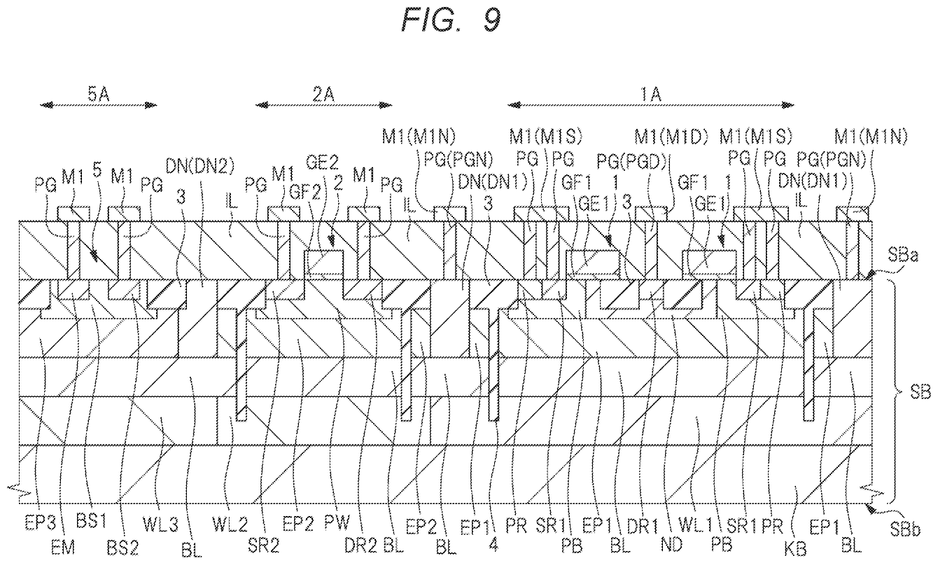

FIG. 9 is a cross-sectional view of the main portion of the semiconductor device of the present third embodiment and shows a cross-section corresponding to FIG. 1.

The semiconductor device of the third embodiment shown in FIG. 9 is different from the semiconductor device of the first embodiment (FIGS. 1 and 7) in the following points.

That is, the semiconductor device of the present third embodiment further includes a bipolar transistor 5. Therefore, the upper surface SBa of the semiconductor substrate SB further includes an element region 5A in which the bipolar transistor 5 is formed. The bipolar transistor 5 can be used in an analog circuit or the like.

The semiconductor substrate SB configuring the semiconductor device of the present third embodiment includes a p-type semiconductor region WL3 disposed on the n-type substrate region KB, and the n-type buried layer BL is also formed on the p-type semiconductor region WL3. The n-type semiconductor region WL1, the semiconductor region WL2, and the p-type semiconductor region WL3 are disposed at different positions on the n-type substrate region KB. In the present third embodiment, in the semiconductor substrate SB, an n-type semiconductor region EP3 is formed on the n-type buried layer BL. The p-type semiconductor region EP1, the p-type semiconductor region EP2, and the n-type semiconductor region EP3 are formed on the n-type buried layer BL and spaced apart from each other. In plan view, the n-type semiconductor region EP3 is surrounded by the n-type semiconductor region DN.

Therefore, the bottom surface of the n-type semiconductor region EP3 is in contact with the n-type buried layer BL, and the side surface of the n-type semiconductor region EP3 is in contact with the n-type semiconductor region DN. In other words, the bottom surface of the n-type semiconductor region EP3 is covered with the n-type buried layer BL, and the side surface of the n-type semiconductor region EP3 is covered with the n-type semiconductor region DN. The n-type buried layer BL, the p-type semiconductor region WL3, and the n-type substrate region KB are present in this order under the n-type semiconductor region EP3. The element region 5A overlaps with the n-type semiconductor region EP3 in plan view. An n-type emitter region EM and p-type base regions BS1,BS2 of the bipolar transistor 5 formed in the element region 5A are formed in the n-type semiconductor region EP3 in plan view.

Next, a configuration of the bipolar transistor 5 formed in the element region 5A will be described.

In the semiconductor substrate SB, the p-type base region BS1 is formed in the upper portion (upper layer portion) of the n-type semiconductor region EP3. The p-type base region BS1 reaches the upper surface SBa of the semiconductor substrate SB. The bottom surface of the p-type base region BS1 is in contact with the n-type semiconductor region EP3. In the semiconductor substrate SB, the n-type emitter region EM and the p-type base region BS2 are formed in the p-type base region BS. The impurity concentration (p-type impurity concentration) of the p-type base region BS2 is higher than the impurity concentration (p-type impurity concentration) of the p-type base region BS1.

The n-type emitter region EM functions as an emitter region of the bipolar transistor 5, and the p-type base regions BS1,BS2 function as a base region of the bipolar transistor 5. The n-type semiconductor region EP3 may function as a collector region of the bipolar transistor 5.

The plug PG disposed on the n-type emitter region EM is electrically connected to the n-type emitter region EM. In addition, the plug PG disposed on the p-type base region BS2 is electrically connected to the plug PG disposed on the p-type base region BS2. The plug PG (not shown in FIG. 9) electrically connected to the n-type semiconductor region EP3 is also formed.

In addition, a metal silicide layer (not shown) may be formed on each of the upper portions (surface layer portions) of the n-type emitter region EM and the p-type base region BS.

Other configurations of the semiconductor device of the third embodiment are substantially the same as those of the semiconductor device of the first embodiment, and therefore, repeated explanation thereof will be omitted here.

Similarly to the above first embodiment, in the present third embodiment, when the drain region (n-type drain region DR1) of the LDMOSFET 1 has a negative potential, electrons injected from the drain region (n-type drain region DR1) into the semiconductor substrate SB can be accurately discharged from the n-type semiconductor region DN1 to the plug PGN. Consequently, when the drain region (n-type drain region DR1) of the LDMOSFET 1 has a negative potential, electrons injected from the drain region (n-type drain region DR1) into the semiconductor substrate SB do not reach the semiconductor region WL2 or the p-type semiconductor region EP2, and do not reach the p-type semiconductor region WL3 or the n-type semiconductor region EP3. Therefore, even if electrons are injected from the drain region (n-type drain region DR1) to the semiconductor substrate SB when the drain region (n-type drain region DR1) of the LDMOSFET 1 has a negative potential, the MISFET 2 formed in the element region 2A of the semiconductor substrate SB is not adversely affected, and the bipolar transistor 5 formed in the element region 5A of the semiconductor substrate SB is not adversely affected. Therefore, the performance of the semiconductor device can be improved.

In addition, the present third embodiment may be applied to the second embodiment.

### Fourth Embodiment

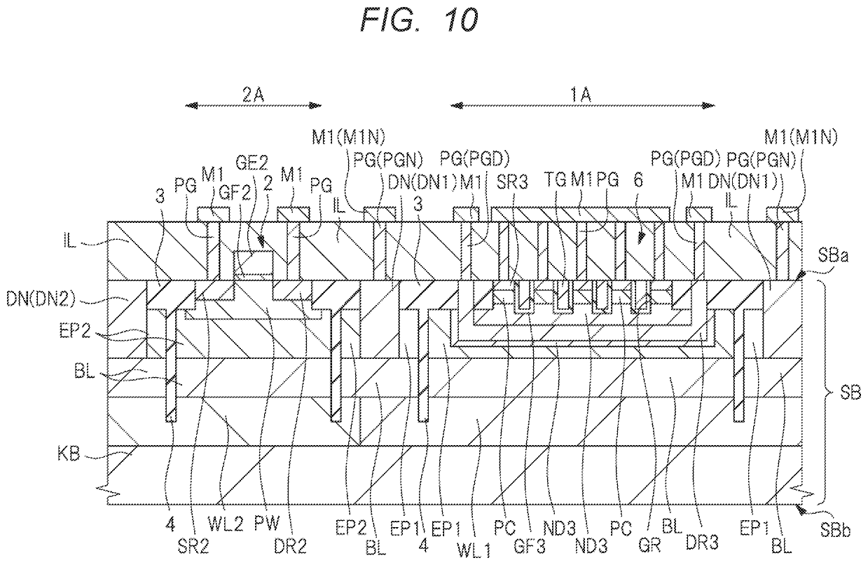

FIG. 10 is a cross-sectional view of the main portion of the semiconductor device of the present fourth embodiment and shows a cross-section corresponding to FIG. 1.

The semiconductor device of the present fourth embodiment shown in FIG. 10 is different from the semiconductor device of the first embodiment (FIGS. 1 and 7) in the following points.

The semiconductor device of the present fourth embodiment includes a trench gate type MISFET 6 instead of the LDMOSFET 1. Therefore, in the semiconductor substrate SB configuring the semiconductor device of the present fourth embodiment, the trench gate type MISFET 6 is formed in the element region 1A instead of the LDMOSFET 1. Similar to the LDMOSFET 1, the trench gate type MISFET 6 is also an n-type (n-channel type) transistor.

A configuration of the trench gate type MISFET 6 formed in the element region 1A will be described below.

In the semiconductor substrate SB, an n-type semiconductor region (n-type drift layer, n-type well) ND3 is formed in an upper portion (upper layer portion) of the p-type semiconductor region EP1, and an n-type source region SR3 and a p-type semiconductor region PC are formed in an upper portion (upper layer portion) of the n-type semiconductor region ND3.

The bottom surface and the side surface of the n-type semiconductor region ND3 are covered with the p-type semiconductor region EP1.

In the element region 1A, a trench (gate trench) GR for a gate electrode is formed in the upper surface SBa of the semiconductor substrate SB, and a trench gate electrode TG is buried in the trench GR via a gate dielectric film GF3.

The source region SR3 is formed in the uppermost layer at a position adjacent to the trench GR in the semiconductor substrate SB, the p-type semiconductor region PC is formed under the source region SR3, and the n-type semiconductor region ND3 is present under the p-type semiconductor region PC. The trench GR penetrates through the source region SR3 and the p-type semiconductor region PC, and the bottom surface of the trench GR is located in the middle of the thickness of the n-type semiconductor region ND3.

In the semiconductor substrate SB, an n-type drain region DR3 is formed in the n-type semiconductor region ND3. The impurity concentration (n-type impurity concentration) of the n-type drain region DR3 is higher than the impurity concentration (n-type impurity concentration) of the n-type semiconductor region ND3. The n-type drain region DR3 integrally includes, under the trench GR, a region extending in the horizontal direction (a direction substantially parallel to the upper surface SBa or the back surface SBb of the semiconductor substrate SB) and a region reaching the upper surface SBa of the semiconductor substrate SB from the outer peripheral portion of the region.

The n-type source region SR3 functions as a source region of the trench gate type MISFET 6, the n-type drain region DR3 functions as a drain region of the trench gate type MISFET 6, and the trench gate electrode TG functions as a gate electrode of the trench gate type MISFET 6.

When a voltage equal to or higher than the threshold voltage is applied to the trench gate electrode TG, an n-type inversion layer is formed in the p-type semiconductor region PC adjacent to the trench GR. The n-type inversion layer serves as a channel. The n-type source region SR3 and the n-type drain region DR3 conduct via the channel and the n-type semiconductor region ND3. The trench gate type MISFET 6 is an n-channel type MISFET. Since the n-type semiconductor region ND3 having a lower impurity concentration than the n-type drain region DR3 is interposed between the p-type semiconductor region PC which is a channel forming region and the n-type drain region DR3, the n-type semiconductor region ND3 can function as an n-type drift region.

The plug PG disposed on the source region SR3 is electrically connected to the source region SR3. The plug PG (PGD) disposed on the n-type drain region DR3 is electrically connected to the n-type drain region DR3. The plug PG (not shown in FIG. 10) electrically connected to the trench gate electrode TG and the plug PG (not shown in FIG. 10) electrically connected to the p-type semiconductor region PC are also formed.

Other configurations of the semiconductor device of the fourth embodiment are substantially the same as those of the semiconductor device of the first embodiment, and therefore, repeated explanation thereof will be omitted here.

Similarly to the above first embodiment, in the present fourth embodiment, when the MISFET 6 formed in the element region 1A is used as the power transistor TR2 for the low-side switch (see FIGS. 3 to 5), the drain region (n-type drain region DR3) of the MISFET 6 may have a negative potential. When the drain region (n-type drain region DR3) of the MISFET 6 has a negative potential, electrons are injected from the drain region (n-type drain region DR3) into the semiconductor substrate SB. If the electrons move in the semiconductor substrate SB and are injected into the p-type semiconductor region EP2, the characteristics of the MISFET 2 formed in the element region 2A may be affected, which leads to a decrease in the performance of semiconductor device, which is undesirable. That is, the problem described in the above first embodiment is not limited to the case where the power switching element formed in the element region 1A is an LDMOSFET, and may also occur when the power switching element formed in the element region 1A is a trench gate type MISFET.

Similarly to the above first embodiment, also in the present fourth embodiment, in the semiconductor substrate SB configuring the semiconductor device, the n-type buried layer BL, the n-type semiconductor region WL1, and the n-type substrate region KB are present in this order under the p-type semiconductor region EP1 and the n-type semiconductor region DN1. Therefore, in the semiconductor substrate SB, the regions under the p-type semiconductor region EP1 and the n-type semiconductor region DN1 are all n-type regions (n-type regions formed of the n-type buried layer BL, the n-type semiconductor region WL1, and the n-type substrate region KB). Thus, when the drain region (n-type drain region DR3) of the MISFET 6 has a negative potential, electrons injected from the drain region (n-type drain region DR3) of the MISFET 6 through the n-type semiconductor region ND3 and the p-type semiconductor region EP1 into the n-type buried layer BL under the p-type semiconductor region EP1 pass through only the n-type region without passing through the p-type region, and are discharged from the n-type semiconductor region DN1 to the plug PGN. In this case, the electrons can move in the n-type region as majority carriers according to the potential gradient. Electrons injected from the drain region of the MISFET 6 into the semiconductor substrate SB can be accurately discharged from the n-type semiconductor region DN1 to the plug PGN. Consequently, the performance of the semiconductor device can be improved. In addition, it is possible to reduce the size (area reduction) of the semiconductor device.

The invention made by the present inventor has been described above in detail based on the embodiment, but the present invention is not limited to the embodiment described above, and it is needless to say that various modifications can be made without departing from the gist thereof.

What is claimed is:

1. A semiconductor device comprising:
a semiconductor substrate having an upper surface including a first element region and a second element region and a back surface opposite to the upper surface;
a first transistor of a first conductivity type formed in the first element region;
a second transistor formed in the second element region;
an interlayer dielectric film formed on the upper surface of the semiconductor substrate so as to cover the first transistor and the second transistor; and
contact plugs buried in the interlayer dielectric film,
wherein the semiconductor substrate includes:
a substrate region of the first conductivity type reaching the back surface;
a first semiconductor region of the first conductivity type and a second semiconductor region of the first conductivity type or a second conductivity type opposite to the first conductivity type, the first semiconductor region and the second semiconductor region being disposed at different positions on the substrate region;
a buried layer of the first conductivity type formed on the first semiconductor region and the second semiconductor region;
a third semiconductor region of the second conductivity type and a fourth semiconductor region of the second conductivity type, the third semiconductor region and the fourth semiconductor region being formed on the buried layer and spaced apart from each other; and
a fifth semiconductor region of the first conductivity type reaching the upper surface from the buried layer,
wherein a first contact plug of the contact plugs is disposed on the fifth semiconductor region and electrically connected to the fifth semiconductor region,
wherein the buried layer, the first semiconductor region and the substrate region are present under the third semiconductor region and the fifth semiconductor region,
wherein the buried layer, the second semiconductor region and the substrate region are present under the fourth semiconductor region,
wherein, in plan view, the first element region is included in the third semiconductor region,
wherein, in plan view, the second element region is included in the fourth semiconductor region, and
wherein, in plan view, the fifth semiconductor region is interposed between the third semiconductor region and the fourth semiconductor region.

2. The semiconductor device according to claim 1,
wherein the first conductivity type is an n-type,
wherein the first transistor is an n-channel type MISFET, and
wherein a potential higher than a potential of the third semiconductor region is supplied from the first contact plug to the fifth semiconductor region.

3. The semiconductor device according to claim 2,
wherein a positive potential is supplied from the first contact plug to the fifth semiconductor region.

4. The semiconductor device according to claim 2,
wherein the first transistor is an LDMOSFET.

5. The semiconductor device according to claim 1, comprising:
a power conversion circuit including a high-side transistor and a low-side transistor connected in series,
wherein the first transistor is used as the low-side transistor in the power conversion circuit.

6. The semiconductor device according to claim 1,
wherein a withstand voltage of the first transistor is larger than a withstand voltage of the second transistor.

7. The semiconductor device according to claim 1,
wherein the first transistor is a power switching element.

8. The semiconductor device according to claim 1,
wherein, in plan view, the fifth semiconductor region surrounds the third semiconductor region.

9. The semiconductor device according to claim 1,
wherein an impurity concentration of the buried layer is higher than an impurity concentration of each of the first semiconductor region and the substrate region.

10. The semiconductor device according to claim 9,
wherein the impurity concentration of the first semiconductor region is higher than the impurity concentration of the substrate region.

11. The semiconductor device according to claim 1,
wherein the semiconductor substrate includes:
a source region of the first conductivity type of the first transistor and a drain region of the first conductivity type of the first transistor, the source region and the drain region being formed in the third semiconductor region and spaced apart from each other;
a first well region formed in the fourth semiconductor region; and
a second source region of the second transistor and a second drain region of the second transistor, the second source region and the second drain region being formed in the first well region and spaced apart from each other,
wherein a first gate electrode of the first transistor is formed on the upper surface of the semiconductor substrate between the source region and the drain region via a gate dielectric film, and
wherein a second gate electrode of the second transistor is formed on the upper surface of the semiconductor substrate between the second source region and the second drain region via a second gate dielectric film.

12. The semiconductor device according to claim 1,
wherein a region under the third semiconductor region and the fifth semiconductor region in the semiconductor substrate is all the region of the first conductivity type.

13. The semiconductor region according to claim 1,
wherein an STI region and a DTI region deeper than the STI region are formed in the semiconductor substrate.

14. The semiconductor region according to claim 13,
wherein the DTI region formed in the third semiconductor region penetrates through the third semiconductor region and the buried layer and reaches the first semiconductor region, and
wherein the DTI region formed in the fourth semiconductor region penetrates through the fourth semiconductor region and the buried layer and reaches the second semiconductor region.

15. The semiconductor device according to claim 1,
wherein the semiconductor substrate includes:
a sixth semiconductor region of the first conductivity type covering a side surface of the fourth semiconductor region; and
a seventh semiconductor region of the second conductivity type interposed between the fifth semiconductor region and the sixth semiconductor region,
wherein the fifth semiconductor region covers a side surface of the third semiconductor region,
wherein the seventh semiconductor region penetrates through the buried layer and reaches the second semiconductor region, and
wherein the second semiconductor region is of the second conductivity type.
